(19) United States
(12) Patent Application Publication
(10) Pub. No.: US 2026/0310867 A1
(43) Pub. Date: Oct. 8, 2026

(54) CIRCUIT TOPOLOGY SYNTHESIS USING LARGE LANGUAGE MODELS AND REINFORCEMENT LEARNING

(71) Applicant: International Business Machines Corporation, Armonk, NY (US)

(72) Inventors: Prashanth Vijayaraghavan, Fremont, CA (US); Luyao Shi, Santa Clara, CA (US); Xin Zhang, Chappaqua, NY (US)

(21) Appl. No.: 19/097,913

(22) Filed: Apr. 2, 2025

(51) Int. Cl. G06F 30/327; G06N 3/092

(52) U.S. Cl. CPC G06F 30/327; G06N 3/092

(57) ABSTRACT

Examples described herein provide for synthesis of an analog circuit using a large language model (LLM) and reinforcement learning (RL). Aspects include receiving an instruction prompt specifying a plurality of design constraints, including a component pool for the analog circuit, a minimum efficiency for the analog circuit, and output voltage for the analog circuit, inputting the instruction prompt into a fine-tuned LLM, and receiving, from the fine-tuned LLM, a circuit topology. Aspects also include applying RL to the circuit topology, wherein the RL includes defining a reward function that evaluates the circuit topology based on criteria and calculating a reward score for the circuit topology, iteratively refining, by the fine-tuned LLM, the circuit topology by inputting the circuit topology, the reward score, and the instruction prompt into the fine-tuned LLM, and based on a determination that the circuit topology meets the plurality of design constraints, outputting the circuit topology.

### BACKGROUND

The disclosure relates to computer systems, specifically to methods and systems for circuit topology synthesis using large language models and reinforcement learning.

In the realm of electronic design automation (EDA), the synthesis of analog circuit topologies presents significant challenges due to the vast design search space and the complexity of adhering to stringent design constraints. Traditional methods for designing and optimizing circuit topologies are often labor-intensive, requiring extensive human expertise and numerous simulation iterations. These approaches struggle with scalability and adaptability, particularly when faced with complex design requirements such as component selection, efficiency optimization, and output voltage regulation. As electronic systems grow increasingly complex, the limitations of these conventional methods become more pronounced, highlighting the need for more efficient and automated solutions.

Existing algorithms, including rule-based systems and genetic algorithms, have been employed to address circuit synthesis tasks. However, these methods often encounter difficulties in efficiently adapting to evolving design specifications and require substantial computational resources due to their reliance on comprehensive simulations. These challenges are further compounded by the need to balance multiple design objectives at the same time, which traditional approaches are not well-equipped to handle.

### SUMMARY

According to one aspect of the present invention, a computer-implemented method for circuit topology synthesis using large language models and reinforcement learning is provided. The method includes receiving an instruction prompt specifying a plurality of design constraints, including a component pool for the analog circuit, a minimum efficiency for the analog circuit, and output voltage for the analog circuit, inputting the instruction prompt into a fine-tuned LLM, and receiving, from the fine-tuned LLM, a circuit topology. The method also includes applying reinforcement learning to the circuit topology, wherein the reinforcement learning includes defining a reward function that evaluates the circuit topology based on one or more criteria and calculating a reward score for the circuit topology, iteratively refining, by the fine-tuned LLM, the circuit topology by inputting the circuit topology, the reward score, and the instruction prompt into the fine-tuned LLM, and based on a determination that the circuit topology meets the plurality of design constraints, outputting the circuit topology.

Embodiments also include computer systems and computer program products for circuit topology synthesis using large language models and reinforcement learning.

The above features and advantages, and other features and advantages, of the disclosure, are readily apparent from the following detailed description when taken in connection with the accompanying drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 is a block diagram illustrating a computing environment, according to one or more embodiments;

FIG. 2 is a block diagram illustrating a system for fine-tuning a pretrained LLM using incident encoding and training data, according to one or more embodiments;

FIG. 3 is a block diagram illustrating is a block diagram illustrating a system for synthesizing circuit topologies using a fine-tuned LLM and reinforcement learning, according to one or more embodiments;

FIG. 4 illustrates a transformation of a netlist into a natural language structure, according to one or more embodiments;

FIG. 5 is a system diagram illustrating the process of generating and simulating a circuit topology using a fine-tuned LLM and a Spice simulator, according to one or more embodiments;

FIG. 6 is a block diagram illustrating a system for circuit topology generation using RLAIF and RL algorithm PPO tuning, according to one or more embodiments; and

FIG. 7 is a flow chart diagram illustrating a method for synthesizing an analog circuit using a fine-tuned LLM and reinforcement learning, according to one or more embodiments.

The detailed description explains embodiments of the disclosure, together with advantages and features, by way of example with reference to the drawings.

### DETAILED DESCRIPTION

In the realm of electronic design automation (EDA), the synthesis of analog circuit topologies presents a significant challenge due to the vast design search space and the need for strict adherence to design constraints. Traditional methods for designing and optimizing circuit topologies are predominantly human led, requiring extensive expertise and time. These methods often involve iterative numerical simulations to explore potential designs, which can be both time-consuming and computationally expensive. As the complexity of modern electronic systems, particularly in power converters, continues to grow, the limitations of these traditional approaches become increasingly apparent.

Existing algorithms for circuit synthesis, such as rule-based systems, heuristic approaches, and genetic algorithms, have shown some success but often struggle with scalability and adaptability to evolving design requirements. These methods typically require a significant number of simulation queries to achieve a design that meets the specified targets, making them inefficient for large-scale automated systems. Moreover, they lack precise control over specific circuit requirements, such as the number of components, target efficiency, and power conversion ratio, which are important for optimizing circuit performance.

In exemplary embodiments, large language models (LLMs) and reinforcement learning (RL) are used to automate the synthesis of analog circuit topologies. This method transforms circuit synthesis problems into a language-like structure, allowing for more efficient exploration of the design space. By incorporating design constraints during the synthesis process and utilizing RL-based refinement, the framework enhances the efficiency, scalability, and generalization capabilities of the topology generation process. This approach minimizes the need for extensive simulation queries and enables the generation of circuits that meet multiple design objectives simultaneously, marking a significant advancement in EDA.

Methods, systems, and computer program products for synthesizing analog circuit topologies by integrating large language models (LLMs) with reinforcement learning (RL) are provide. In exemplary embodiments, the integration of LLMs and RL allows for the efficient processing of instruction prompts that specify design constraints, such as component pool, efficiency, and output voltage. By inputting these prompts into a fine-tuned LLM, a circuit topology is generated that is then refined through reinforcement learning. The RL process involves defining a reward function to evaluate the topology based on specific criteria, which guides the iterative refinement of the design. This approach significantly reduces the need for extensive simulation queries traditionally required in circuit design, thereby accelerating the design process and enhancing scalability. The ability to iteratively refine the circuit topology ensures that the final output meets the specified design constraints, providing a more efficient and automated solution compared to conventional methods. This results in a practical application that addresses the challenges of scalability and adaptability in electronic design automation, particularly for complex design requirements.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

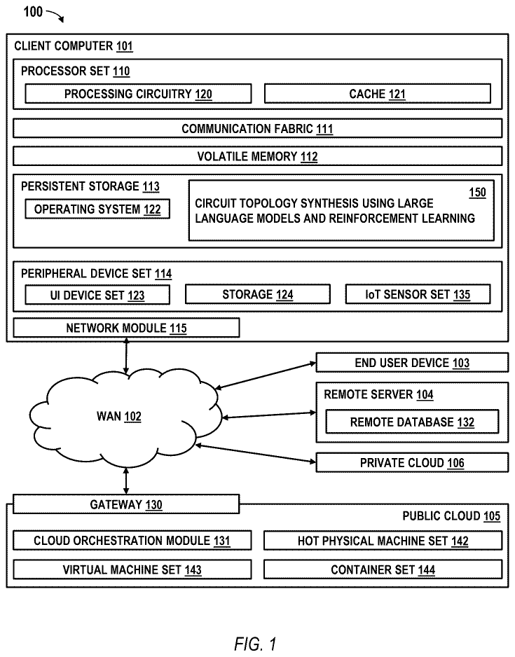

FIG. 1 illustrates a computing environment 100, according to an embodiment. Computing environment 100 contains an example of an environment for the execution of at least some of the computer code includes providing anomaly detection based self-health check system for monitoring products, as shown at block 150. In addition to a controller for controlling the operations of a metal cutting tool, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122, as identified above), peripheral device set 114 (including user interface (UI) device set 123, storage 124, and Internet of Things (IoT) sensor set 135), and network module 115. Remote server 104 includes remote database 132. Public cloud 105 includes gateway 130, cloud orchestration module 131, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in persistent storage 113 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 135 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 132 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 131. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 131 manages the transfer and storage of images, deploys new instantiations of VCEs and manages active instantiations of VCE deployments. Gateway 130 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the owner of the entity is also updated).

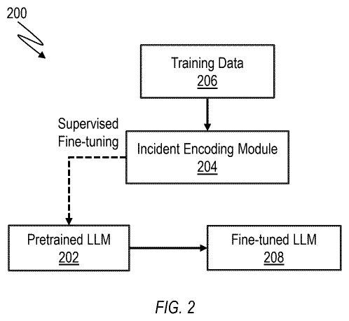

Referring now to FIG. 2, a block diagram of a system 200 for creating a fine-tuned LLM for synthesizing analog circuit topologies in accordance with an exemplary embodiment is shown. In exemplary embodiments, the system 200 includes a pretrained LLM 202 that functions as a foundational model that has undergone initial training on a broad dataset to comprehend general language patterns and structures. The pretrained LLM 202, may be any pretrained LLM such as Llama models offered by Meta, CHATGPT models offered by OpenAI, and the like. The pretrained LLM 202 has baseline capabilities for understanding and generating language-like structures. The pretrained LLM 202 is fine-tuned to evolve into the fine-tuned LLM 208, which is specifically tailored to process and generate circuit designs based on specified constraints.

In exemplary embodiments, the incident encoding module 204 is configured to transform a netlist, or component pool, of a circuit into a language-like structure. The incident encoding module 204 receives training data 206 that includes netlists for circuits and encodes the netlists using the incident encoding method. The incident encoding method involves representing circuit topologies represented by the netlist as sequences of tokens, where each token corresponds to a component or connection in the circuit. The output of the incident encoding module 204 and the training data 206 are provided to the pre-trained LLM 202 to create a fined-tuned LLM 208. In exemplary embodiments, the fine-tuned LLM 208 can effectively process and generate circuit designs based on the specified constraints, such as netlist, efficiency, and output voltage.

In exemplary embodiments, the training data 206 is a collection of data that includes pairs of instruction prompts and corresponding circuit topology netlists. The training data 206 is used to fine-tune the pretrained LLM 202 through supervised learning, resulting in the fined-tuned LLM 208. The training data is used to teach the pre-trained LLM 202 to generate valid circuit topologies from instruction prompts that specify design constraints, such as component pool, efficiency, and output voltage.

In exemplary embodiments, the fined-tuned LLM 208 is the result of fine-tuning the pre-trained LLM 202 using the training data 206 and the incident encoding method. The fined-tuned LLM 208 is specifically designed to process instruction prompts and generate circuit topologies that adhere to specified design constraints. The fined-tuned LLM 208 can generate initial circuit designs, which are then further optimized through reinforcement learning to ensure they meet the desired performance metrics.

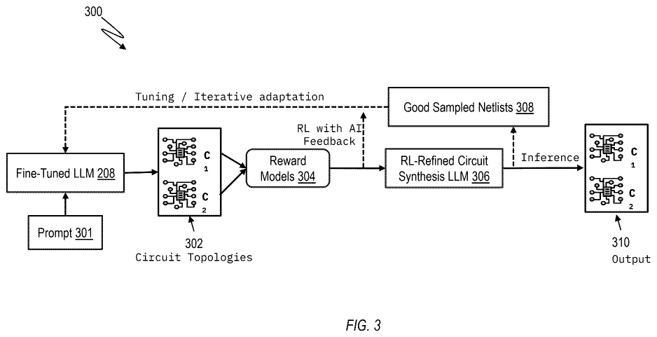

Referring now to FIG. 3, a block diagram of a system 200 for synthesizing ab analog circuit topology using a fine-tuned LLM and reinforcement learning in accordance with an exemplary embodiment is shown. In exemplary embodiments, the system 300 is designed to automate the generation and refinement of analog circuit topologies by leveraging advanced machine learning techniques. The system 300 begins with a prompt 301, which serves as the initial input to a fine-tuned LLM 208. The prompt 301 contains specific design constraints and requirements that guide the synthesis process. The fine-tuned LLM 208, which has been trained to understand and generate circuit designs, processes the prompt 301 to produce initial circuit topologies 302. These circuit topologies 302 are represented in a structured format that allows for further analysis and refinement.

The circuit topologies 302 generated by the fine-tuned LLM 208 are then evaluated using reward models 304. The reward models 304 are used to assess the quality and performance of the circuit topologies 302 based on predefined criteria such as circuit validity, efficiency, and output voltage. The reward models 304 provide feedback, which is used to guide the reinforcement learning process. The RL feedback mechanism ensures that the generated circuit topologies 302 are iteratively improved to meet the specified design constraints more effectively.

In exemplary embodiments, the RL-refined circuit synthesis LLM 306 is configured to incorporate the feedback from the reward models 304 and to refine the circuit topologies 302. The RL-refined circuit synthesis LLM 306 utilizes reinforcement learning techniques to adjust the parameters of the RL-refined circuit synthesis LLM 306, enhancing the ability to generate high-quality circuit designs. The iterative adaptation process allows the system 300 to learn from previous iterations and continuously improve the synthesis process.

In exemplary embodiments, the good sampled netlists 308 are selected from the refined circuit topologies created by the RL-refined circuit synthesis LLM 306 based on their performance metrics. The good sampled netlists 308 represent the most promising designs that meet the desired criteria and are used as the basis for further optimization and validation. The selection process ensures that only the most efficient and valid designs are considered for final output.

In exemplary embodiments, the good sampled netlists 308, along with the corresponding output of the reward models 304, are used to further fine-tune the fine-tuned LLM 208. This step involves using the selected netlists and feedback to refine the LLM's parameters, enhancing its ability to generate circuit topologies that adhere to the specified design constraints. This further fine-tuning process helps in improving the model's performance and ensuring that the generated designs are optimized for the given requirements.

The output 310 of the system 300 represents the culmination of the iterative synthesis process, resulting in a final set of circuit topologies that have been both refined and validated. In exemplary embodiments, the information included in the output 310 may include a variety of information that includes: refined circuit topologies that meet the specified design constraints provided in the initial prompt 301; validation metrics that demonstrate adherence to predefined criteria such as circuit validity, efficiency, and output voltage, derived from evaluations conducted by the reward models 304; detailed design specifications for each circuit topology, including component configurations, connections, and relevant parameters defining the circuit's functionality; performance metrics such as efficiency ratings, expected output voltage, and other relevant electrical characteristics to provide a comprehensive understanding of each circuit's capabilities. Overall, the output 310 serves as a comprehensive package of refined and validated circuit topologies, complete with all necessary information to support their implementation in real-world electronic design scenarios.

In exemplary embodiments, the instruction tuning phase can be considered as a standard supervised finetuning (SFT) step, where instruction prompts specifying the component pool and design constraints are provided as input to the model, and the corresponding circuit topology generations are produced as output. The pairs of instruction-circuit topologies are represented as

$$𝒟 = {\{ \text{?} ( {X}_{i} , {Y}_{i} ) \}}_{i = 1}^{T} \text{?} ,$$

$$\text{?} \text{indicates text missing or illegible when filed}$$

where Xi denotes the instruction prompt and Yi represents the valid circuit topology netlist using the incident encoding method concatenated with the corresponding duty cycle. In exemplary embodiments, this phase involves training an autoregressive language model pθ parameterized by θ to minimize the negative log-likelihood of the desired circuit topology represented using the incident encoding method.

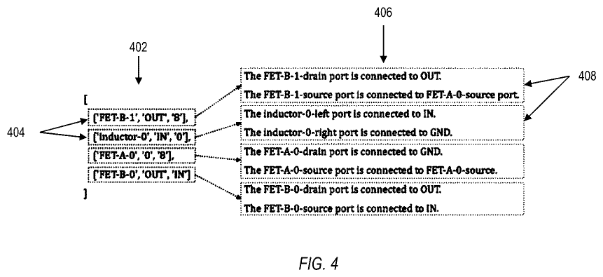

Referring now to FIG. 4, a transformation of a netlist 402 into a natural language structure (NLS) 408 in accordance with an exemplary embodiment is shown. In exemplary embodiments, the transformation process involves transforming each entry 404, which is a component of the Netlist 402, into a NLS 408 format to create a transformed netlist 406. The netlist 402 is a structured representation of an analog circuit, detailing the components and their interconnections. This representation serves as the starting input for the transformation process. The netlist 402 includes multiple entries 404, each specifying a component and the connections of that component within the circuit. In exemplary embodiments, each entry 404 corresponds to a circuit element within a circuit and contains specific information about the circuit element, such as the type of element and the ports to which the element connects. The information provided by each entry 404 provides the detailed data needed to convert the netlist 402 into a format that is comprehensible by an LLM. In exemplary embodiments, the transformed netlist 406 is the result of processing each entry 404 from the Netlist 402. This transformed version represents the same circuit information but in a format that is more accessible for further analysis and processing by an LLM. Each entry 404 of the netlist 402 is transformed into a natural NLS 408 that represents the concluding output of the transformation process. In exemplary embodiments, the NLS 408 for each entry 404 contains two lines of text that describe the circuit element and its connection. The NLS 408 provides a human-readable description of the circuit's components and their connections, which can be processed and understood by an LLM.

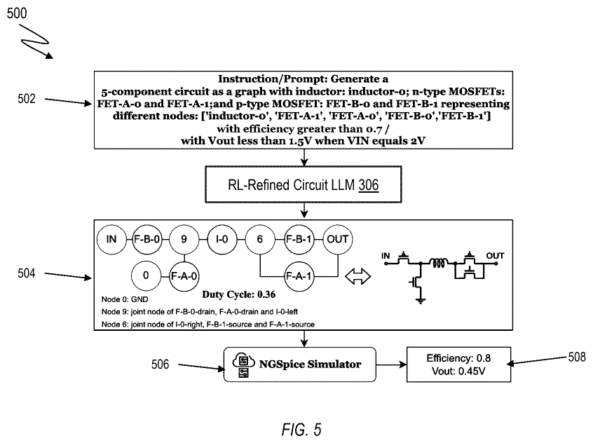

Referring now to FIG. 5 a system 500 for synthesizing an analog circuit topology in accordance with an exemplary embodiment, is shown. The system 500 is configured to receive a prompt 502 from a user and input the prompt into a RL-refined circuit synthesis LLM 306. Based on the prompt 502, the RL-refined circuit synthesis LLM 306 generates an output 504 that includes one or more circuit topologies that satisfy the constraints included in the prompt 501. In exemplary embodiments, the system 500 is designed to automate the generation and evaluation of circuit designs by leveraging advanced machine learning techniques and simulation tools.

In exemplary embodiments, the prompt 502 serves as the initial input to the system 500, containing specific design constraints and requirements that guide the synthesis process. The prompt specifies the components and performance criteria for the circuit, such as the types of MOSFETs and inductors to be used, as well as efficiency and output voltage targets. In exemplary embodiments, the output 504 represents the circuit topology generated by the system 500 based on the input from the prompt 502. This output includes a detailed schematic of the circuit, showing the arrangement and connections of the components as specified in the prompt 502. The output 504 is structured to allow for further analysis and refinement. In exemplary embodiments, the generated circuit topology, the circles represent components or connections in the circuit, where “F” indicates a “FET” (field-effect transistor) and “I” indicates an inductor.

In exemplary embodiments, the spice simulator 506 is used to simulate the performance of the circuit topology generated in the output 504. The spice simulator 506 provides a virtual environment to test and validate the circuit's behavior under various conditions, ensuring that the circuit meets the specified design constraints. In exemplary embodiments, the spice simulator 506 is configured to provide circuit characteristics 508 based on the operation of the simulated circuit. The circuit characteristics 508 can include the efficiency and output voltage of the circuit topology.

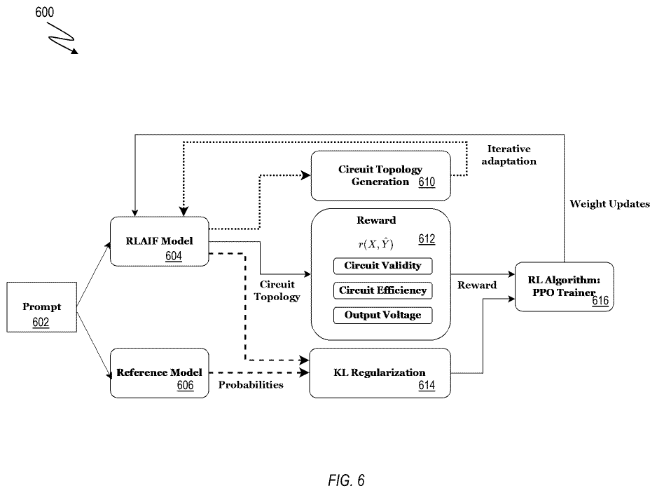

FIG. 6 illustrates a system 600 for refining circuit topology generation using reinforcement learning with AI feedback (RLAIF) in accordance with exemplary embodiments. The system 600 is configured to enhance the synthesis of analog circuit topologies by integrating feedback from constraint-specific AI models. The system 600 is configured to generate a circuit topology based on a user provide prompt 602. The prompt 602 specifies the design constraints for the desired circuit topology. The system 600 includes a RLAIF model 604 that is configured to process the prompt 602 and generates initial circuit topologies. The RLAIF model 604 model leverages reinforcement learning techniques to iteratively improve the generated designs based on feedback from reward models.

In exemplary embodiments, the system 600 also includes a reference model 606 that is configured to provide a baseline for evaluating the circuit topologies generated by the RLAIF model 604. The reference model 606 helps maintain the original distribution of the supervised instruction-tuned model by factoring in Kullback-Leibler (KL) divergence during the reward calculation.

In exemplary embodiments, the system 600 also includes a circuit topology generation module 610 that is configured to generate circuit topologies based on the input prompt 602. In exemplary embodiments, the generation process is guided by the reward module 612, which evaluates the designs against specific criteria.

In exemplary embodiments, the reward module 612 is configured assesses the generated circuit topologies based on criteria such as circuit validity, efficiency, and expected output voltage. It assigns a reward score to each topology, which is used to guide the reinforcement learning process. In one embodiment, the reward module 612 includes a circuit validity estimator, a circuit efficiency estimator, and an output voltage estimator and the output of the reward module is a combination of the output of the circuit validity estimator, a circuit efficiency estimator, and an output voltage estimator.

In one embodiment, the circuit validity estimator generates a binary classifier, s_{valid}, and the circuit validity estimator is trained on a dataset D comprising valid and invalid circuits to determine the validity of circuit topologies. In exemplary embodiment, the circuit validity estimator is a RoBERTa-based classifier that achieves a 92% F₁ score for binary classification of circuit validity. In one embodiment, the circuit efficiency estimator is a regression model that generates an estimate (s_{eff}) of a circuit efficiency using a subset of the dataset D with prompts specifying efficiency requirements. The circuit efficiency estimator model achieves an 83% macro F₁ score by categorizing predicted efficiency scores into predefined categories.

In one embodiment, the output voltage estimator is a regression model that generates a predicted output voltage (sᵥₒᵤₜ) based on input parameters, achieving a low MSE loss of 8e⁻³ on the development set.

Using the remaining data in D and the trained estimators, a reward function r(X, Ŷ) can be defined that assigns a reward to an LLM-generated circuit topology Ŷ as follows:

$$r ( X , \hat{Y} ) = \{ \begin{matrix}- 1 , & if {s}_{valid} < 0.6 \\ 1 , & if {s}_{eff} or {s}_{vout} meets constraints \\ {s}_{eff} , & otherwise\end{matrix}$$

In exemplary embodiments, the reward module 612 is configured to generate a negative reward if the generated circuit topology is invalid. If the generated circuit topology is valid and meets constraints related to output voltage or efficiency specified in the prompt, a reward of 1 is assigned. Otherwise, the efficiency estimate serves as the reward.

In exemplary embodiments, the system 600 also includes a KL regularization module 614 that is configured to apply KL regularization to the reward function to prevent the model from deviating too far from the original distribution of the instruction-tuned model. This regularization helps maintain the balance between exploration and exploitation during the learning process. In exemplary embodiments, the system 600 also includes a RL algorithm proximal policy optimization (PPO) tuning module 616. The PPO algorithm is employed to refine the model parameters based on the reward scores. This algorithm optimizes the circuit topology generation process by iteratively updating the model weights to enhance the quality of the designs.

In exemplary embodiments, the system 600 utilizes an iterative adaptation process, where the generated circuit topologies are continuously refined based on the feedback from the reward models. This approach ensures that the final designs meet the specified design constraints more effectively, resulting in high-quality circuit topologies that adhere to the desired performance metrics.

In exemplary embodiments, to further enhance the performance of the fine-tuned LLM for generating circuit topologies that better meet the constraints, a reward function r(X, Ŷ) and proximal policy optimization (PPO) is utilized. The fine-tuned LLM is refined using Reinforcement Learning with Human Feedback (RLHF). Standard PPO training procedures are also applied to optimize the fine-tuned LLM using the following reward objective function:

$${ℒ}_{RL} = r ( X , \hat{Y} ) - η KL ( {π}_{RLAIF} ( \hat{Y} \vert X ) \vert \vert {π}_{θ} ( \hat{Y} \vert X ) )$$

where, KL represents the Kullback-Leibler divergence, and n is a hyperparameter controlling the penalty for divergence. This penalty helps prevent the fine-tuned LLM from getting trapped in local optima or straying too far from the original distribution of the fine-tuned LLM.

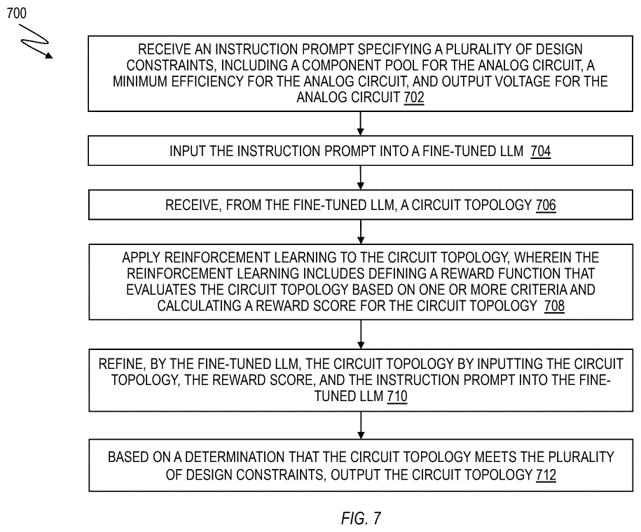

Referring now to FIG. 7, a flow chart illustrating a method 700 for synthesizing an analog circuit using a large language model (LLM) and reinforcement learning (RL), according to one or more embodiments is shown. The method 700 can be implemented by a system 300, such as the one shown in FIG. 3.

The method 700 for synthesizing an analog circuit using a large language model (LLM) and reinforcement learning (RL) begins at block 702 by receiving an instruction prompt specifying a plurality of design constraints. These constraints include a component pool for the analog circuit, a minimum efficiency for the analog circuit, and output voltage for the analog circuit. In one embodiment, the output voltage constraint is an expected output voltage relative to the input voltage. The instruction prompt serves as the initial input to the system, guiding the synthesis process by detailing the specific requirements that the generated circuit topology needs to meet.

Next, as shown at block 704, the method 700 includes inputting the instruction prompt into a fine-tuned LLM. The fine-tuned LLM is specifically trained to process these prompts and generate circuit topologies that align with the given constraints. This step leverages the capabilities of the fine-tuned LLM to interpret the language-like structure of the prompts and transform them into viable circuit designs. The fine-tuning process ensures that the fine-tuned LLM is adept at understanding the nuances of circuit design requirements, thereby enhancing the accuracy and relevance of the generated topologies.

Following this, at block 706, the method 700 involves receiving, from the fine-tuned LLM, a circuit topology. This step marks the transition from input processing to output generation, where the fine-tuned LLM provides an initial circuit design based on the interpreted constraints. The generated circuit topology serves as a preliminary design that will undergo further refinement to ensure it meets all specified criteria.

As depicted at block 708, the method 700 includes applying reinforcement learning to the circuit topology. This involves defining a reward function that evaluates the circuit topology based on one or more criteria and calculating a reward score for the circuit topology. Next, as shown at block 710, the method 700 includes refining the circuit topology by inputting the circuit topology, the reward score, and the instruction prompt back into the fine-tuned LLM. This iterative process allows the LLM to adjust the design based on the feedback received from the reward function, ensuring that the final output is optimized for the specified constraints. Next, as shown at block 712, the method 700 involves outputting the circuit topology based on a determination that the circuit topology meets the plurality of design constraints. This step signifies the completion of the synthesis process, where the refined circuit design is evaluated against the initial constraints to ensure compliance. Once verified, the design is outputted as the concluding product of the synthesis process, ready for implementation in real-world applications. In exemplary embodiments, the verified circuit topology may be automatically fabricated into an integrated circuit.

In an example scenario, an engineer is tasked with designing an analog circuit that meets specific design constraints, including a component pool, minimum efficiency, and output voltage. The process begins with the engineer providing an instruction prompt detailing these constraints. Initially, a fine-tuned LLM generates a circuit topology based on the interpreted constraints. However, this initial design does not fully meet the specified constraints, as it falls short in terms of efficiency and output voltage. To address this, reinforcement learning is applied to the circuit topology. A reward function is defined to evaluate the circuit based on criteria such as efficiency and output voltage. The initial design receives a low reward score due to its failure to meet the efficiency and output voltage targets. The generated circuit topology is then refined by inputting the circuit topology, the reward score, and the instruction prompt back into the fine-tuned LLM. The fine-tuned LLM uses this feedback to adjust the design, focusing on improving the areas where the initial design was lacking. Through several iterations, the fine-tuned LLM modifies the circuit topology, perhaps by optimizing component values or reconfiguring connections to enhance efficiency and output voltage. Each iteration is evaluated by the reward function, and the design is continuously refined until it achieves a satisfactory reward score, indicating that it meets the specified constraints. This iterative process ensures that the final output is optimized for the specified constraints, resulting in a circuit design that not only meets but potentially exceeds the initial requirements. The engineer can then implement this refined design in real-world applications, confident in its performance and compliance with the design constraints.

In exemplary embodiments, as the iterative process progresses, the fine-tuned LLM not only refines the current circuit topology but also learns from each iteration, enhancing its ability to generate higher-quality initial designs in future tasks. By incorporating the feedback and adjustments made during the refinement process, the fine-tuned LLM updates its internal model parameters, effectively training itself to better understand and meet the specified design constraints. This continuous learning mechanism allows the fine-tuned LLM to improve its predictive accuracy and design efficiency over time, reducing the need for extensive iterations in subsequent projects. As a result, the fine-tuned LLM becomes increasingly adept at producing circuit topologies that are closer to the desired specifications from the outset, streamlining the design process and enabling engineers to achieve optimal solutions more rapidly. This adaptive capability ensures that the fine-tuned LLM remains a valuable tool in the evolving landscape of analog circuit design, consistently delivering innovative and compliant designs with minimal manual intervention.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method for synthesis of an analog circuit using a large language model (LLM) and reinforcement learning (RL), comprising:
receiving an instruction prompt specifying a plurality of design constraints, including a component pool for the analog circuit, a minimum efficiency for the analog circuit, and output voltage for the analog circuit;
inputting the instruction prompt into a fine-tuned LLM;
receiving, from the fine-tuned LLM, a circuit topology;
applying reinforcement learning to the circuit topology, wherein the reinforcement learning includes defining a reward function that evaluates the circuit topology based on one or more criteria and calculating a reward score for the circuit topology;
iteratively refining, by the fine-tuned LLM, the circuit topology by inputting the circuit topology, the reward score, and the instruction prompt into the fine-tuned LLM; and
based on a determination that the circuit topology meets the plurality of design constraints, outputting the circuit topology.

2. The computer-implemented method of claim 1, wherein the fine-tuned LLM is created by fine tuning a pre-trained LLM using supervised learning on a dataset comprising pairs of instruction prompts and corresponding circuit topology netlists.

3. The computer-implemented method of claim 2, wherein the supervised learning includes performing incident encoding to transforming each entry in the circuit topology netlists into a language-like structure that includes an identification of each component and its connections.

4. The computer-implemented method of claim 1, wherein applying reinforcement learning further includes tuning the fine-tuned LLM to maximize the reward function using policy gradient in reinforcement learning.

5. The computer-implemented method of claim 1, wherein the circuit topology includes component configurations, connections, and parameters that define a functionality of a circuit.

6. The computer-implemented method of claim 1, wherein reward function is a weighted function that is based on a circuit validity estimate, an efficiency estimate, and an expected output voltage estimate.

7. The computer-implemented method of claim 6, wherein the circuit validity estimate is created based on a trained binary classifier that determines a validity of the circuit topology, the efficiency estimate is created by a regression model that estimates an efficiency of the circuit topology, and the expected output voltage estimate is created by a regression model that estimates an output voltage of the circuit topology.

8. A system comprising:
a memory comprising computer readable instructions; and
a processing device for executing the computer readable instructions, the computer readable instructions controlling the processing device to perform operations comprising:
receiving an instruction prompt specifying a plurality of design constraints, including a component pool for an analog circuit, a minimum efficiency for the analog circuit, and output voltage for the analog circuit;
inputting the instruction prompt into a fine-tuned LLM;
receiving, from the fine-tuned LLM, a circuit topology;
applying reinforcement learning to the circuit topology, wherein the reinforcement learning includes defining a reward function that evaluates the circuit topology based on one or more criteria and calculating a reward score for the circuit topology;
iteratively refining, by the fine-tuned LLM, the circuit topology by inputting the circuit topology, the reward score, and the instruction prompt into the fine-tuned LLM; and
based on a determination that the circuit topology meets the plurality of design constraints, outputting the circuit topology.

9. The system of claim 8, wherein the fine-tuned LLM is created by fine tuning a pre-trained LLM using supervised learning on a dataset comprising pairs of instruction prompts and corresponding circuit topology netlists.

10. The system of claim 9, wherein the supervised learning includes performing incident encoding to transforming each entry in the circuit topology netlists into a language-like structure that includes an identification of each component and its connections.

11. The system of claim 8, wherein applying reinforcement learning further includes tuning the fine-tuned LLM to maximize the reward function using policy gradient in reinforcement learning.

12. The system of claim 8, wherein the circuit topology includes component configurations, connections, and parameters that define a functionality of a circuit.

13. The system of claim 8, wherein reward function is a weighted function that is based on a circuit validity estimate, an efficiency estimate, and an expected output voltage estimate.

14. The system of claim 13, wherein the circuit validity estimate is created based on a trained binary classifier that determines a validity of the circuit topology, the efficiency estimate is created by a regression model that estimates an efficiency of the circuit topology, and the expected output voltage estimate is created by a regression model that estimates an output voltage of the circuit topology.

15. A computer program product for performing self-health checks in monitoring products, the computer program product comprising:
a set of one or more computer-readable storage media;
program instructions, collectively stored in the set of one or more storage media, for causing a processor set to perform the following computer operations:
receiving an instruction prompt specifying a plurality of design constraints, including a component pool for an analog circuit, a minimum efficiency for the analog circuit, and output voltage for the analog circuit;
inputting the instruction prompt into a fine-tuned LLM;
receiving, from the fine-tuned LLM, a circuit topology;
applying reinforcement learning to the circuit topology, wherein the reinforcement learning includes defining a reward function that evaluates the circuit topology based on one or more criteria and calculating a reward score for the circuit topology;
iteratively refining, by the fine-tuned LLM, the circuit topology by inputting the circuit topology, the reward score, and the instruction prompt into the fine-tuned LLM; and
based on a determination that the circuit topology meets the plurality of design constraints, outputting the circuit topology.

16. The computer program product of claim 15, wherein the fine-tuned LLM is created by fine tuning a pre-trained LLM using supervised learning on a dataset comprising pairs of instruction prompts and corresponding circuit topology netlists.

17. The computer program product of claim 16, wherein the supervised learning includes performing incident encoding to transforming each entry in the circuit topology netlists into a language-like structure that includes an identification of each component and its connections.

18. The computer program product of claim 15, wherein applying reinforcement learning further includes tuning the fine-tuned LLM to maximize the reward function using policy gradient in reinforcement learning.

19. The computer program product of claim 15, wherein the circuit topology includes component configurations, connections, and parameters that define a functionality of a circuit.

20. The computer program product of claim 15, wherein reward function is a weighted function that is based on a circuit validity estimate, an efficiency estimate, and an expected output voltage estimate.
